(19) United States
(12) Patent Application Publication
(10) Pub. No.: US 2015/0014155 A1
(43) Pub. Date: Jan. 15, 2015

(54) Ferromagnetic Material Sputtering Target Containing Chromium Oxide

(71) Applicant: JX Nippon Mining & Metals Corporation, Tokyo (JP)

(72) Inventors: Hideo Takami, Ibaraki (JP); Atsutoshi Arakawa, Ibaraki (JP)

(21) Appl. No.: 14/380,113

(22) PCT Filed: Jan. 15, 2013
(86) PCT No.: PCT/JP2013/050530

§ 371 Date: Aug. 21, 2014

(30) Foreign Application Priority Data
Feb. 23, 2012 (JP) 2012-037235

(51) Int. Cl. H01J 37/34; C23C 14/14

(52) U.S. Cl. CPC H01J 37/3426; C23C 14/14; H01J 37/3429; H01J 2237/332
USPC 204/298.13

(57) ABSTRACT

Provided is a ferromagnetic material sputtering target containing a matrix phase made of cobalt, or cobalt and chromium, or cobalt and platinum, or cobalt, chromium and platinum, and an oxide phase including at least a chromium oxide, wherein the sputtering target contains one or more types of Zr and W in a total amount of 100 wt ppm or more and 15000 wt ppm or less, and has a relative density of 97% or higher. An object of this invention is to provide a ferromagnetic material sputtering target containing chromium oxide with low generation of particles capable of maintaining high density and with uniformly pulverized oxide phase grains.

### BACKGROUND

The present invention relates to a ferromagnetic material sputtering target for use in deposition of a magnetic thin film for a magnetic recording medium, and particularly a magnetic recording layer of a hard disk adopting the perpendicular magnetic recording system, and also relates to a sputtering target capable of inhibiting the generation of particles during sputtering.

In the field of magnetic recording represented by hard disk drives, a material based on a ferromagnetic metal Co, Fe or Ni is used as a material for a magnetic thin film in a magnetic recording medium. For recording layers of hard disks adopted for the recently commercialized perpendicular magnetic recording system, composite materials of a Co—Cr based or Co—Cr—Pt based ferromagnetic alloy containing Co as the main component and a nonmagnetic inorganic substance are used.

A magnetic thin film for a magnetic recording medium such as a hard disk is often produced by sputtering a ferromagnetic material sputtering target having the foregoing materials as its components for its high productivity. In recent years, for a hard disk used for a magnetic recording device, a higher recording density has been demanded and the reduction of particles that are generated during sputtering is also strongly demanded pursuant to the increase in recording density.

For example, Patent Literature 1, 2 and 3 describe sputtering targets configured from a magnetic phase of a cobalt-based metal and a nonmagnetic phase of a metal oxide, wherein the generation of particles and arcing during spattering is reduced by pulverizing grains in the oxide phase. However, since a chromium oxide sintering is not easily sintered, if chromium oxide is subject to sufficient sintering, there are cases where grains of components other than the chromium oxide will grow and; when a target with a coarse structure resulting from the foregoing grain growth is sputtered, there is a problem in that generation of particles will increase. Meanwhile, if sintering is inhibited in order to suppress the foregoing grain growth, the target density will deteriorate and there is a similar problem in that the generation of particles will increase.

### PRIOR ART DOCUMENT

### Patent Document

Patent Document 1: Japanese Patent Laid-Open No. 2009-215617

Patent Document 2: WO2007/080781

Patent Document 3: Japanese Patent No. 4837801

### SUMMARY OF INVENTION

### Technical Problem

Generally, if a magnetron sputtering device is used to sputter a ferromagnetic material sputtering target, there is a problem in that the generation of particles and arcing will occur during sputtering resulting from the oxide phase. In order to resolve the foregoing problem, considered may be pulverizing the oxide phase particles and uniformly dispersing such particles in the sputtering target material. Nevertheless, since a chromium oxide is a material that is not easily sintered, it is difficult to uniformly pulverizing the oxide phase grains which contain a chromium oxide phase, while maintaining high density. In light of the foregoing problem, an object of this invention is to provide a ferromagnetic material sputtering target containing chromium oxide with low generation of particles capable of maintaining high density and with uniformly pulverized oxide phase grains. However, since a chromium oxide is a material that is not easily sintered, it is difficult to uniformly pulverize oxide phase while maintaining a high density.

### Solution to Problem

As a result of intense study to solve the above problem, the present inventors have found that by containing Zr or W, which can serve as sintering additives, it is possible to obtain a high-density ferromagnetic material sputtering target with uniformly pulverized oxide phase grains.

Based on the finding, the present invention provides:

1) a ferromagnetic material sputtering target containing a matrix phase made of cobalt, or cobalt and chromium, or cobalt and platinum, or cobalt, chromium and platinum, and an oxide phase including at least a chromium oxide, wherein the sputtering target contains one or more types of Zr and W in a total amount of 100 wt ppm to 15000 wt ppm, and has a relative density of 97% or higher,

2) the ferromagnetic material sputtering target according to 1), wherein the chromium oxide is contained in an amount of 0.5 mol % or more and 10 mol % or less in the Cr₂O₃ conversion,

3) the ferromagnetic material sputtering target according to 1) or 2), wherein the oxide phase contains the chromium oxide and one or more types of a metal oxide of Ti and Ta in a total amount of 5 mol % or more and 25 mol % or less,

4) the ferromagnetic material sputtering target according to any one of 1) to 3), containing one or more types of Zr and W in a total amount of 100 wt ppm or more and 3000 wt ppm or less, and

5) the ferromagnetic material sputtering target according to any one of 1) to 4), wherein an average grain size of the oxide phase is 3 μm²/grain or less.

### Effects of Invention

As described above, a high-density ferromagnetic material sputtering target can be obtained by including a predetermined amount of zirconium (Zr) and/or tungsten (W). Moreover, a sputtering target prepared in this way yields a superior effect of being able to reduce the generation of arcing and particles during sputtering.

### DETAILED DESCRIPTION

Main components of the ferromagnetic material sputtering target of the present invention are metals of cobalt (Co), cobalt (Co) and chromium (Cr), cobalt (Co) and platinum (Pt), or cobalt (Co), chromium (Cr) and platinum (Pt). These are components required as magnetic recording media. There is no particular limitation in the mixing ratio so as long as the ratio falls within a range where properties of effective magnetic recording media can be maintained. In general, those mixed in the following ratios are used: Co: 50 mol % or more; or Cr: 1 to 50 mol % and the remainder being Co; Pt: 5 to 30 mol % and the remainder being Co; or Cr: 1 to 50 mol %, Pt: 5 to 30 mol % and the remainder being Co.

Moreover, other than the foregoing metals, ruthenium (Ru) and boron (B) may be used as components.

What is important in the present invention is that a target contains a chromium oxide as an oxide phase, and one or more types of Zr and W in a total amount of 100 wt ppm or more and 15000 wt ppm or less. Thus, when Zr or W is contained in a target including a chromium oxide, it becomes possible to inhibit the coarsening of the structure while maintaining high density, since Zr or W can promote sintering of the chromium oxide by serving as sintering additives. In the present invention, there is no particular limitation in the method of including these elements so as long as one or more types of Zr and W are included in a total amount of 100 wt ppm or more and 15000 wt ppm or less in the target.

Preferably, either one or both of Zr and W are contained in a total amount of 100 wt ppm or more and 15000 wt ppm or less. This is because oxide phase grains may be subject to grain growth when the amount is less than 100 wt ppm while intended magnetic properties cannot be obtained when it exceeds 15000 wt ppm. A content of 100 wt ppm or more and 3000 wt ppm or less is more preferred.

As described above, Zr and W have a function to promote sintering of a chromium oxide. Therefore, coarsening of structure can be more effectively inhibited by selecting the content of Zr or W depending on the content of the chromium oxide; for example, the content of Zr or W may be increased when the content of the chromium oxide is large while the content of Zr or W may be reduced when the content of the chromium oxide is small.

The ferromagnetic material sputtering target of the present invention preferably has a relative density of 97% or higher. It is generally known that a target having a higher density can reduce an amount of particles generated during sputtering. Here, the term “relative density” refers to a value that is obtained by dividing the measured density of the target by the calculated density (also known as the theoretical density) of the target.

In the present invention, a chromium oxide contained in an amount of 0.5 mol % or more and 10 mol % or less in the Cr₂O₃ conversion is effective. When the amount of a chromium oxide exceeds 10 mol %, it becomes difficult to adjust the oxide grain size.

Moreover, in the present invention, a metal oxide of one or more types of Ti and Ta further contained in a total amount (including a chromium oxide) of 5 mol % or more and 25 mol % or less is effective. These are elements added as intended in order to improve properties of a magnetic recording medium. When the total amount of the foregoing metal oxides is less than 5 mol %, it becomes difficult to maintain a granular structure, but when the total amount of the foregoing metal oxides exceeds 25 mol %, the adjustment of the oxide grain size becomes difficult. Moreover, in the present invention, while metal oxides of Ti and Ta are particularly effective in obtaining superior characteristics of a magnetic recording medium, a similar effect can be obtained by including oxides of B, Co and the like.

In the ferromagnetic material sputtering target of the present invention, an average grain size of oxide phases of 3 μm²/grain or less is effective. The average grain size (diameter) can be obtained by computing each grain area using image processing in an image taken at a magnification enough to identifying 100 or more oxide grains, and calculating the total grain area/the total grain number. An average grain size of oxide phases of more than 3 μm²/grain is not preferred since the amount of particles will increase.

The ferromagnetic material sputtering target of the present invention may be manufactured by the powder metallurgy method.

Foremost, a powder of the respective metal element and a powder of the respective oxide are prepared. Preferably, an average grain size of these metal powders is 20 μm or less. An alloy powder of these metals may be prepared in substitute for a powder of the respective metal element, and in the foregoing case, the average grain size is also preferably 20 μm or less. Meanwhile, if the grain size is too small, oxidation may be further promoted, and the component composition will not fall within the intended range. Thus, preferably, the grain size is 0.1 μm or more. The oxide powders preferably have an average grain size of 5 μm or less; and more preferably, 1 μm or less.

Subsequently, these metal powders and oxide powders are weighed to the intended composition, mixed and pulverized with well-known methods by using a ball mill or the like.

Subsequently, ZrO₂ powder and WO₃ powder are prepared. For W, metal (W) powder and carbonized carbide (WC) powder can be used. For these powders, those having an average grain size of 1 μm or less are preferably used. However, since powders may be easily flocculated if the grain size is too small, powders having an average grain size of 0.1 μm or more are preferably used.

This powder is added to the mixture of the metal powders and the oxide powders, and mixing and pulverization is performed. Here, it is also possible to mix an oxide powder as an additive and Cr₂O₃ powder in advance, perform calcination thereto, and use the resulting pulverized powder as a raw material.

When considering the problem of oxidation during the mixing process, mixing is preferably performed in an inert gas atmosphere or in a vacuum. Moreover, mixing and pulverization are preferably performed until the average grain size of these powders becomes 1 μm or less.

The ferromagnetic material sputtering target of the present invention is prepared by molding and sintering the obtained powder using a vacuum hot pressing device, and cutting the resulting product into an intended shape. Note that the molding and sintering process is not limited to hot pressing, and plasma discharge sintering and hot isostatic sintering may also be used. The holding temperature during sintering is preferably set to the lowest temperature in a temperature range in which the target can be sufficiently densified. While this will also depend on the target composition, in many cases, the holding temperature is within the temperature range of 800 to 1200° C.

### EXAMPLES

The present invention is now explained in detail with reference to the

Examples and Comparative Examples. Note that Examples are presented for merely illustrative purposes, and the present invention shall in no way be limited thereby. That is, the present invention is limited only by the claims, and shall encompass various modifications other than those in Examples included in the present invention.

### Example 1

As metal raw material powders, Co powder having an average grain size of 6 μm, Cr powder having an average grain size of 5 μm and Pt powder having an average grain size of 9 μm were prepared, and as oxide raw material powders, TiO₂ powder having an average grain size of 2 μm and Cr₂O₃ powder having an average grain size of 3 μm were prepared.

Subsequently, the raw material powders were weighed and mixed to achieve a target composition of Co-10Cr-20Pt-5Cr₂O₃-5TiO₂. ZrO₂ powder was additionally added to the foregoing mixed powder in an amount of 0.1 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98%, and a high density target was obtained. Further, the observation of a structure of the target showed that an average grain size of the oxide phase was 1.2 μm²/grain, and fine grains were obtained. Upon performing a compositional analysis of a sample acquired from the target, it was confirmed that the amount of Zr relative to the total component amount was 1000 wt ppm. Moreover, upon conducting a sputtering evaluation of the target, the number of particles was 3, and a favorable result was obtained.

### Example 2

As metal raw material powders, Co powder having an average grain size of 6 μm, Cr powder having an average grain size of 5 μm and Pt powder having an average grain size of 9 μm were prepared, and as oxide raw material powders, TiO₂ powder having an average grain size of 2 μm and Cr₂O₃ powder having an average grain size of 3 μm were prepared.

Subsequently, the raw material powders were weighed and mixed to achieve a target composition of Co-10Cr-20Pt-5Cr₂O₃-5TiO₂. ZrO₂ powder was additionally added to the foregoing mixed powder in an amount of 0.01 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 1050° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 97.5%, and a high density target was obtained. Further, the observation of a structure of the target showed that an average grain size of the oxide phase was 1.8 μm²/grain, and fine grains were obtained. Upon performing a compositional analysis of a sample acquired from the target, it was confirmed that the amount of Zr relative to the total component amount was 100 wt ppm. Moreover, upon conducting a sputtering evaluation of the target, the number of particles was 10, and a favorable result was obtained.

### Example 3

As metal raw material powders, Co powder having an average grain size of 6 μm, Cr powder having an average grain size of 5 μm and Pt powder having an average grain size of 9 μm were prepared, and as oxide raw material powders, TiO₂ powder having an average grain size of 2 μm and Cr₂O₃ powder having an average grain size of 3 μm were prepared.

Subsequently, the raw material powders were weighed and mixed to achieve a target composition of Co-10Cr-20Pt-5Cr₂O₃-5TiO₂. ZrO₂ powder was additionally added to the foregoing mixed powder in an amount of 1.5 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 1050° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 99.5%, and a high density target was obtained. Further, the observation of a structure of the target showed that an average grain size of the oxide phase was 1.9 μm²/grain, and fine grains were obtained. Upon performing a compositional analysis of a sample acquired from the target, it was confirmed that the amount of Zr relative to the total component amount was 15000 wt ppm. Moreover, upon conducting a sputtering evaluation of the target, the number of particles was 9, and a favorable result was obtained.

### Example 4

As metal raw material powders, Co powder having an average grain size of 6 μm, Cr powder having an average grain size of 5 μm and Pt powder having an average grain size of 9 μm were prepared, and as oxide raw material powders, TiO₂ powder having an average grain size of 2 μm and Cr₂O₃ powder having an average grain size of 3 μm were prepared.

Subsequently, the raw material powders were weighed and mixed to achieve a target composition of Co-10Cr-20Pt-5Cr₂O₃-5TiO₂. WO₃ powder was additionally added to the foregoing mixed powder in an amount of 0.05 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 1050° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98%, and a high density target was obtained. Further, the observation of a structure of the target showed that an average grain size of the oxide phase was 1.2 μm²/grain, and fine grains were obtained. Upon performing a compositional analysis of a sample acquired from the target, it was confirmed that the amount of W relative to the total component amount was 1000 wt ppm. Moreover, upon conducting a sputtering evaluation of the target, the number of particles was 3, and a favorable result was obtained.

### Example 5

As metal raw material powders, Co powder having an average grain size of 6 μm, Cr powder having an average grain size of 5 μm and Pt powder having an average grain size of 9 μm were prepared, and as oxide raw material powders, TiO₂ powder having an average grain size of 2 μm and Cr₂O₃ powder having an average grain size of 3 μm were prepared.

Subsequently, the raw material powders were weighed and mixed to achieve a target composition of Co-10Cr-20Pt-5Cr₂O₃-5TiO₂. WO₃ powder was additionally added to the foregoing mixed powder in an amount of 0.005 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 1050° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 97.6%, and a high density target was obtained. Further, the observation of a structure of the target showed that an average grain size of the oxide phase was 1.7 μm²/grain, and fine grains were obtained. Upon performing a compositional analysis of a sample acquired from the target, it was confirmed that the amount of W relative to the total component amount was 100 wt ppm. Moreover, upon conducting a sputtering evaluation of the target, the number of particles was 6, and a favorable result was obtained.

### Example 6

As metal raw material powders, Co powder having an average grain size of 6 μm, Cr powder having an average grain size of 5 μm and Pt powder having an average grain size of 9 μm were prepared, and as oxide raw material powders, TiO₂ powder having an average grain size of 2 μm and Cr₂O₃ powder having an average grain size of 3 μm were prepared.

Subsequently, the raw material powders were weighed and mixed to achieve a target composition of Co-10Cr-20Pt-5Cr₂O₃-5TiO₂. WO₃ powder was additionally added to the foregoing mixed powder in an amount of 0.75 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 1050° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 99.4%, and a high density target was obtained. Further, the observation of a structure of the target showed that an average grain size of the oxide phase was 2.1 μm²/grain, and fine grains were obtained. Upon performing a compositional analysis of a sample acquired from the target, it was confirmed that the amount of W relative to the total component amount was 15000 wt ppm. Moreover, upon conducting a sputtering evaluation of the target, the number of particles was 10, and a favorable result was obtained.

### Example 7

As metal raw material powders, Co powder having an average grain size of 6 μm, Cr powder having an average grain size of 5 μm and Pt powder having an average grain size of 9 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-10Cr-20Pt-5Cr₂O₃-5TiO₂. ZrO₂ powder in an amount of 0.02 mol % and WO₃ powder in an amount of 0.01 mol % were additionally added to the foregoing mixed powder, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 1050° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 99%, and a high density target was obtained. Further, the observation of a structure of the target showed that an average grain size of the oxide phase was 1.3 μm²/grain, and fine grains were obtained. Upon performing a compositional analysis of a sample acquired from the target, it was confirmed that the amount of Zr relative to the total component amount was 200 wt ppm and the amount of W was 200 wt ppm. Moreover, upon conducting a sputtering evaluation of the target, the number of particles was 5, and a favorable result was obtained.

### Example 8

As metal raw material powders, Co powder having an average grain size of 6 μm and Cr powder having an average grain size of 5 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-10Cr-5Cr₂O₃-20TiO₂. ZrO₂ powder was additionally added to the foregoing mixed powder in an amount of 0.74 mol %, and the resulting mixed powder was pulverized in an inert atmosphere until the average grain size thereof became 1 μm or less. f

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 99.2%, and a high density target was obtained. Further, the observation of a structure of the target showed that an average grain size of the oxide phase was 2.7 μm²/grain, and fine grains were obtained. Upon performing a compositional analysis of a sample acquired from the target, it was confirmed that the amount of Zr relative to the total component amount was 10000 wt ppm. Moreover, upon conducting a sputtering evaluation of the target, the number of particles was 12, and a favorable result was obtained.

### Example 9

As metal raw material powders, Co powder having an average grain size of 6 μm and Cr powder having an average grain size of 5 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-10Cr-0.5Cr₂O₃-12TiO₂. ZrO₂ powder was additionally added to the foregoing mixed powder in an amount of 0.007 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 99.5%, and a high density target was obtained. Further, the observation of a structure of the target showed that an average grain size of the oxide phase was 2 μm²/grain, and fine grains were obtained. Upon performing a compositional analysis of a sample acquired from the target, it was confirmed that the amount of Zr relative to the total component amount was 100 wt ppm. Moreover, upon conducting a sputtering evaluation of the target, the number of particles was 5, and a favorable result was obtained.

### Example 10

As metal raw material powders, Co powder having an average grain size of 6 μm and Cr powder having an average grain size of 5 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-10Cr-10Cr₂O₃-5TiO₂. ZrO₂ powder was additionally added to the foregoing mixed powder in an amount of 0.15 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98.2%, and a high density target was obtained. Further, the observation of a structure of the target showed that an average grain size of the oxide phase was 1.5 μm²/grain, and fine grains were obtained. Upon performing a compositional analysis of a sample acquired from the target, it was confirmed that the amount of Zr relative to the total component amount was 2000 wt ppm. Moreover, upon conducting a sputtering evaluation of the target, the number of particles was 7, and a favorable result was obtained.

### Example 11

As metal raw material powders, Co powder having an average grain size of 6 μm and Cr powder having an average grain size of 5 μm were prepared, and as oxide raw material powders, Cr₂O₃ powder having an average grain size of 3 μm, TiO₂ powder having an average grain size of 2 μm and CoO powder having an average grain size of 5 μm were prepared.

Subsequently, the raw material powders were weighed and mixed to achieve a target composition of Co-10Cr-5Cr₂O₃-5TiO₂-2CoO. ZrO₂ powder was additionally added to the foregoing mixed powder in an amount of 0.16 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98%, and a high density target was obtained. Further, the observation of a structure of the target showed that an average grain size of the oxide phase was 1.8 μm²/grain, and fine grains were obtained. Upon performing a compositional analysis of a sample acquired from the target, it was confirmed that the amount of Zr relative to the total component amount was 2200 wt ppm. Moreover, upon conducting a sputtering evaluation of the target, the number of particles was 7, and a favorable result was obtained.

### Example 12

As metal raw material powders, Co powder having an average grain size of 6 μm and Cr powder having an average grain size of 5 μm were prepared, and as oxide raw material powders, Cr₂O₃ powder having an average grain size of 3 μm, TiO₂ powder having an average grain size of 2 μm and a B₂O₃ powder having an average grain size of 5 μm were prepared.

Subsequently, the raw material powders were weighed and mixed to achieve a target composition of Co-10Cr-5Cr₂O₃-5TiO₂-2B₂O₅. ZrO₂ powder was additionally added to the foregoing mixed powder in an amount of 0.13 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98.8%, and a high density target was obtained. Further, the observation of a structure of the target showed that an average grain size of the oxide phase was 2.3 μm²/grain, and fine grains were obtained. Upon performing a compositional analysis of a sample acquired from the target, it was confirmed that the amount of Zr relative to the total component amount was 1800 wt ppm. Moreover, upon conducting a sputtering evaluation of the target, the number of particles was 11, and a favorable result was obtained.

### Example 13

As metal raw material powders, Co powder having an average grain size of 6 μm and Cr powder having an average grain size of 5 μm were prepared, and as oxide raw material powders, Cr₂O₃ powder having an average grain size of 3 μm and TiO₂ powder having an average grain size of 2 μm and Ta₂O₃ powder having an average grain size of 5 μm were prepared.

Subsequently, the raw material powders were weighed and mixed to achieve a target composition of Co-10Cr-5Cr₂O₃-5TiO₂-2Ta₂O₃. ZrO₂ powder was additionally added to the foregoing mixed powder in an amount of 0.21 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98.4%, and a high density target was obtained. Further, the observation of a structure of the target showed that an average grain size of the oxide phase was 2.1 μm²/grain, and fine grains were obtained. Upon performing a compositional analysis of a sample acquired from the target, it was confirmed that the amount of Zr relative to the total component amount was 2600 wt ppm. Moreover, upon conducting a sputtering evaluation of the target, the number of particles was 8, and a favorable result was obtained.

### Example 14

As metal raw material powders, Co powder having an average grain size of 6 μm, Cr powder having an average grain size of 5 μm and a Ru powder having an average grain size of 10 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-10Cr-5Ru-5Cr₂O₃-5TiO₂. ZrO₂ powder was additionally added to the foregoing mixed powder in an amount of 0.07 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 97.8%, and a high density target was obtained. Further, the observation of a structure of the target showed that an average grain size of the oxide phase was 1.8 μm²/grain, and fine grains were obtained. Upon performing a compositional analysis of a sample acquired from the target, it was confirmed that the amount of Zr relative to the total component amount was 1000 wt ppm. Moreover, upon conducting a sputtering evaluation of the target, the number of particles was 9, and a favorable result was obtained.

### Example 15

As metal raw material powders, Co powder having an average grain size of 6 μm, Cr powder having an average grain size of 5 μm, Pt powder having an average grain size of 9 μm and a Ru powder having an average grain size of 10 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-5Cr-15Pt-5Ru-3Cr₂O₃-7TiO₂. ZrO₂ powder was additionally added to the foregoing mixed powder in an amount of 0.05 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98.5%, and a high density target was obtained. Further, the observation of a structure of the target showed that an average grain size of the oxide phase was 1.9 μm²/grain, and fine grains were obtained. Upon performing a compositional analysis of a sample acquired from the target, it was confirmed that the amount of Zr relative to the total component amount was 500 wt ppm. Moreover, upon conducting a sputtering evaluation of the target, the number of particles was 10, and a favorable result was obtained.

### Example 16

As metal raw material powders, Co powder having an average grain size of 6 μm, Cr powder having an average grain size of 5 μm, Pt powder having an average grain size of 9 μm and B powder having an average grain size of 10 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-5Cr-15Pt-5B-3Cr₂O₃-7TiO₂. ZrO₂ powder was additionally added to the foregoing mixed powder in an amount of 0.035 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 950° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98.8%, and a high density target was obtained. Further, the observation of a structure of the target showed that an average grain size of the oxide phase was 1.7 μm²/grain, and fine grains were obtained. Upon performing a compositional analysis of a sample acquired from the target, it was confirmed that the amount of Zr relative to the total component amount was 400 wt ppm. Moreover, upon conducting a sputtering evaluation of the target, the number of particles was 5, and a favorable result was obtained.

### Comparative Example 1

As metal raw material powders, Co powder having an average grain size of 6 μm, Cr powder having an average grain size of 5 μm and Pt powder having an average grain size of 9 μm were prepared, and as oxide raw material powders, TiO₂ powder having an average grain size of 2 μm and Cr₂O₃ powder having an average grain size of 3 μm were prepared.

Subsequently, the raw material powders were weighed and mixed to achieve a target composition of Co-10Cr-20Pt-5Cr₂O₃-5TiO₂. Neither ZrO₂ powder nor WO₃ powder was added.

Thereafter, the pulverized mixed powder was filled in a carbon mold, and hot pressed in a vacuum atmosphere under conditions of a temperature of 1150° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 99% while the observation of a structure of the target showed that an average grain size of the oxide phase was 3.6 μm²/grain, and the sputtering evaluation of the target showed that the number of particles was 20. Upon performing a compositional analysis of a sample acquired from the target, it was confirmed that the amount of Zr and W relative to the total component content were respectively less than 10 ppm, i.e. less than the detection limit.

Accordingly, with Comparative Example 1, when neither ZrO₂ powder nor WO₃ powder was added, and a sintering temperature was increased due to a decreased density, the oxide phase grains were subject to grain growth and the intended particle properties were not obtained.

### Comparative Example 2

As metal raw material powders, Co powder having an average grain size of 6 μm and Cr powder having an average grain size of 5 μm were prepared, and as oxide raw material powders, Cr₂O₃ powder having an average grain size of 3 μm and TiO₂ powder having an average grain size of 2 μm were prepared.

Subsequently, the raw material powders were weighed and mixed to achieve a target composition of Co-10Cr-10Cr₂O₃-20TiO₂. ZrO₂ powder was additionally added to the foregoing mixed powder in an amount of 1.19 mol %, and the resulting mixed powder was pulverized in an inert atmosphere until the average grain size thereof became 1 μm or less.

Thereafter, the pulverized mixed powder was filled in a carbon mold, and hot pressed in a vacuum atmosphere under conditions of a temperature of 1100° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 97%. Further, the observation of a structure of the target showed that an average grain size of the oxide phase was 8.2 μm²/grain. A compositional analysis of the target shows that the number of particles was 61. Upon performing a compositional analysis of a sample acquired from the target, it was confirmed that the amount of Zr relative to the total component amount was 15000 wt ppm.

Accordingly, with Comparative Example 2, since the amount of the oxides was excessive, it was not possible to inhibit the grain growth of the oxide phase grains sufficiently and the intended particle properties were not obtained.

### Comparative Example 3

As metal raw material powders, Co powder having an average grain size of 6 μm and Cr powder having an average grain size of 5 μm were prepared, and as oxide raw material powders, Cr₂O₃ powder having an average grain size of 3 μm was prepared.

Subsequently, the raw material powders were weighed and mixed to achieve a target composition of Co-10Cr-12Cr₂O₃. ZrO₂ powder was additionally added to the foregoing mixed powder in an amount of 1.4 mol %, and was pulverized in an inert atmosphere until the average grain size thereof became 1 μm or less.

Thereafter, the pulverized mixed powder was filled in a carbon mold, and hot pressed in a vacuum atmosphere under conditions of a temperature of 1100° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 97%, and deterioration in the density was observed. Further, the observation of a structure of the target showed that an average grain size of the oxide phase was 4.2 μm²/grain; and a compositional analysis of the target shows that the number of particles was 46. Upon performing a compositional analysis of a sample acquired from the target, it was confirmed that the amount of Zr relative to the total component amount was 18000 wt ppm.

Accordingly, with Comparative Example 3, when the amount of Cr₂O₃ was excessive, it was not possible to inhibit the grain growth of the oxide phase grains sufficiently. Thus, the intended particle properties were not obtained.

### Comparative Example 4

As metal raw material powders, Co powder having an average grain size of 6 μm and Cr powder having an average grain size of 5 μm were prepared, and as oxide raw material powders, TiO₂ powder having an average grain size of 2 μm, Cr₂O₃ powder having an average grain size of 3 μm and CoO powder having an average grain size of 5 μm were prepared.

Subsequently, the raw material powders were weighed and mixed to achieve a target composition of Co-10Cr-5Cr₂O₃-3TiO₂-2CoO. Neither ZrO₂ powder nor WO₃ powder was added.

Thereafter, the pulverized mixed powder was filled in a carbon mold, and hot pressed in a vacuum atmosphere under conditions of a temperature of 1150° C., a holding time of 2 hours and a pressure of 30 MPa to obtain a sintered compact. The obtained sintered compact was cut with a lathe to obtain a disk-shaped target having a diameter of 180 mm and a thickness of 7 mm.

As shown in Table 1, the relative density of the target was 98.5% while the observation of a structure of the target showed that an average grain size of the oxide phase was 3.2 μm²/grain. A compositional analysis of the target shows that the number of particles was 20. Upon performing a compositional analysis of a sample acquired from the target, it was confirmed that the amount of Zr and W relative to the total component content were respectively less than 10 ppm, i.e. less than the detection limit.

Accordingly, with Comparative Example 4, when neither ZrO₂ powder nor WO₃ powder was added and a sintering temperature was increased due to a decreased density, the oxide phase grains were subject to grain growth and the intended particle properties were not obtained.

TABLE 1

| | | Form of | Zr, W Content | Relative | Oxide | Number |
|---|---|---|---|---|---|---|
| | Target Composition | additive | (metal conversion) | density | grain size | of particles |
| | (mol %) | — | (wtppm) | (%) | (μm²/grain) | (particle) |
| Example 1 | Co—10Cr—20Pt—5Cr₂O₃—5TiO₂ | ZrO₂ | 1000 | 98 | 1.2 | 3 |
| Example 2 | Co—10Cr—20Pt—5Cr₂O₃—5TiO₂ | ZrO₂ | 100 | 97.5 | 1.8 | 10 |
| Example 3 | Co—10Cr—20Pt—5Cr₂O₃—5TiO₂ | ZrO₂ | 15000 | 99.5 | 1.9 | 9 |
| Example 4 | Co—10Cr—20Pt—5Cr₂O₃—5TiO₂ | WO₃ | 1000 | 98 | 1.2 | 3 |
| Example 5 | Co—10Cr—20Pt—5Cr₂O₃—5TiO₂ | WO₃ | 100 | 97.6 | 1.7 | 6 |
| Example 6 | Co—10Cr—20Pt—5Cr₂O₃—5TiO₂ | WO₃ | 15000 | 99.4 | 2.1 | 10 |
| Example 7 | Co—10Cr—20Pt—5Cr₂O₃—5TiO₂ | ZrO₂ | 200 | 99 | 1.3 | 5 |
| | | WO₃ | 200 | | | |
| Example 8 | Co—10Cr—5Cr₂O₃—20TiO₂ | ZrO₂ | 10000 | 99.2 | 2.7 | 12 |
| Example 9 | Co—10Cr—0.5Cr₂O₃—12TiO₂ | ZrO₂ | 100 | 99.5 | 2 | 5 |
| Example 10 | Co—10Cr—10Cr₂O₃—5TiO₂ | ZrO₂ | 2000 | 98.2 | 1.5 | 7 |
| Example 11 | Co—10Cr—5Cr₂O₃—5TiO₂—2CoO | ZrO₂ | 2200 | 98 | 1.8 | 7 |
| Example 12 | Co—10Cr—5Cr₂O₃—5TiO₂—2B₂O₃ | ZrO₂ | 1800 | 98.8 | 2.3 | 11 |
| Example 13 | Co—10Cr—5Cr₂O₃—5TiO₂—2Ta₂O₅ | ZrO₂ | 2600 | 98.4 | 2.1 | 8 |
| Example 14 | Co—10Cr—5Ru—5Cr₂O₃—5TiO₂ | ZrO₂ | 1000 | 97.8 | 1.8 | 9 |
| Example 15 | Co—5Cr—15Pt—5Ru—3Cr₂O₃—7TiO₂ | ZrO₂ | 500 | 98.5 | 1.9 | 10 |
| Example 16 | Co—5Cr—15Pt—5B—3Cr₂O₃—7TiO₂ | ZrO₂ | 400 | 98.8 | 1.7 | 5 |
| Comparative | Co—10Cr—20Pt—5Cr₂O₃—5TiO₂ | — | <10 | 99 | 3.6 | 20 |
| Example 1 | | | | | | |
| Comparative | Co—10Cr—10Cr₂O₃—20TiO₂ | ZrO₂ | 15000 | 97 | 8.2 | 61 |
| Example 2 | | | | | | |
| Comparative | Co—10Cr—12Cr₂O₃ | ZrO₂ | 18000 | 97 | 4.2 | 46 |
| Example 3 | | | | | | |
| Comparative | Co—10Cr—5Cr₂O₃—3TiO₂—2CoO | — | <10 | 98.5 | 32 | 20 |
| Example 4 | | | | | | |

From all cases of Examples 1 to 16, it was confirmed that the obtained target has a high-density with oxides finely dispersed therein. Examples revealed that those structure can suppress the amount of particles generated during sputtering, and can play an extremely important role to improve a deposition yield.

The present invention can maintain a high target density and inhibit grain growth including Zr or W in the ferromagnetic material sputtering target containing chromium oxide.

Accordingly, by using a target of the present invention, it is possible to significantly reduce particle generation in sputtering with a magnetron sputtering device.

The present invention is useful as a ferromagnetic material sputtering target for use in the deposition of a magnetic material thin film for a magnetic recording medium, and particularly of a recording layer of a hard disk drive.

1. A ferromagnetic material sputtering target containing a matrix phase made of cobalt, or cobalt and chromium, or cobalt and platinum, or cobalt, chromium and platinum, and an oxide phase including at least a chromium oxide, wherein the ferromagnetic material sputtering target contains one or more types of Zr and W in a total amount equal to or more than 100 wt ppm and less than 15000 wt ppm, the chromium oxide being contained in an amount of 0.5 mol % or more and 10 mol % or less in Cr₂O₃ conversion, and wherein the sputtering target has a relative density of 97% or higher.

2. (canceled)

3. The ferromagnetic material sputtering target according to claim 1, wherein the oxide phase contains the chromium oxide and one or more types of a metal oxide of Ti and Ta in a total amount of 5 mol % or more and 25 mol % or less.

4. The ferromagnetic material sputtering target according to claim 3, containing said one or more types of Zr and W in a total amount of 100 wt ppm or more and 3000 wt ppm or less.

5. The ferromagnetic material sputtering target according to claim 4, wherein an average grain size of the oxide phase is 3 μm²/grain or less.

6. The ferromagnetic material sputtering target according to claim 1, containing said one or more types of Zr and W in a total amount of 100 wt ppm or more and 3000 wt ppm or less.

7. The ferromagnetic material sputtering target according to claim 1, wherein an average grain size of the oxide phase is 3 μm²/grain or less.
